(19) United States
(12) Patent Application Publication
(10) Pub. No.: US 2026/0331403 A1
(43) Pub. Date: Oct. 22, 2026

(54) Switching Device and Power Supply Circuit for Extinguishing Electric Arc

(71) Applicant: Joulwatt Technology Co., Ltd., Hangzhou (CN)

(72) Inventor: Pitleong Wong, Hangzhou (CN)

(21) Appl. No.: 19/529,091

(22) Filed: Feb. 3, 2026

(30) Foreign Application Priority Data
Feb. 14, 2025 (CN) 202510166890.1

(51) Int. Cl. H01H 33/04; G01R 19/165; G01R 19/175; H01H 33/59

(52) U.S. Cl. CPC H01H 33/045; G01R 19/1659; G01R 19/175; H01H 33/59

(57) ABSTRACT

This application discloses a switching device and power supply circuit for extinguishing electric arc. A mechanical switch in an original circuit breaker is replaced by a switching device including a mechanical magnetic switch and an electronic switch connected in parallel. During the disconnection process, the magnetic switch is opened first, and the electronic switch is then turned off. The electronic switch may be controlled to turn off at a zero current, thereby avoiding arcing during disconnection. The switching device eliminates the need for a specialized arc-extinguishing gas, and effectively extinguishes arcing during disconnection. The overall system is simple with extended service life and low cost.

### CROSS-REFERENCE TO RELATED APPLICATIONS

This patent application claims priority to China Patent Application No. 202510166890.1, filed on Feb. 14, 2025 and entitled “SWITCHING DEVICE AND POWER SUPPLY CIRCUIT FOR ELIMINATING ELECTRIC ARC,” which is hereby incorporated by reference herein as if reproduced in its entirety.

### TECHNICAL FIELD

The present disclosure relates generally to the field of power electronics technology, and more specifically, to a switching device and a power supply circuit for eliminating electric arc.

### BACKGROUND

An electric arc is a gas discharge phenomenon that occurs between contacts due to a sharp drop in voltage between the contacts and a sudden interruption of current when a switching device switch off a circuit. The electric arc generated can damage electrical equipments, and measures need to be taken to extinguish it.

The existing mainstream method for extinguishing an electric arc (or referred to simply as arc) is gas blowing. The main principle of the gas blowing arc extinguishing technology is to cause the air pressure at the front end of an arc extinguishing chamber higher than that at the back end of the arc extinguishing chamber by gradually contracting an arc channel, forming an airflow that blows the arc towards the arc extinguishing chamber. The method requires the use of a gas-generating material (such as sulfur hexafluoride SF6 gas) as the arc extinguishing medium, combined with a gradually contracted arc channel (called Laval nozzle). This scheme requires a special arc extinguishing airflow, resulting in high cost and complex control.

Therefore, it is necessary to provide improved technical solutions to overcome the above-mentioned technical problems existing in the art.

### SUMMARY

In view of above, an objective of the present disclosure is to provide a switching device and a power supply circuit for extinguishing an electric arc, so as to solve the technical problems of complex system and high cost in the art.

According to one aspect of the present disclosure, a switching device is provided for extinguishing an electric arc. The switching device is connected between a high-potential terminal and a low-potential terminal, and comprises: a mechanical switch and an electronic switch connected between the high-potential terminal and the low-potential terminal, the magnetic switch and the electronic switch connected in parallel; a voltage drop detection circuit, wherein when the switching device receives an off enable signal, the voltage drop detection circuit and the switching device start to operate, the voltage drop detection circuit detects a voltage between the high-potential terminal and the low-potential terminal, and when the detected voltage drops below a preset first voltage threshold, the voltage drop detection circuit generates a first trigger signal to control the magnetic switch to open; and a switch control circuit, which detects a current in a branch where the electronic switch is located and controls the electronic switch to turn off at an current extreme value, wherein the current extreme value is zero or close to zero.

Optionally, after the first trigger signal is used to control the magnetic switch to open, the switch control circuit controls the electronic switch to remain on.

Optionally, an absolute value of the preset first voltage threshold is any value less than 10 mV.

Optionally, after the first trigger signal controls the magnetic switch to open, and when the voltage drop detection circuit detects that the voltage between the high-potential terminal and the low-potential terminal is greater than a preset second voltage threshold, the voltage drop detection circuit generates a second trigger signal to control the magnetic switch to close, wherein the second voltage threshold is any value greater than 1V.

Optionally, the electronic switch is a bidirectional switch combination.

Optionally, the electronic switch includes a first switch and a second switch connected in series, body diodes of the first switch and the second switch are in opposite directions, and the switch control circuit controls a switch that is to be turned off later in the first switch and the second switch to turn off at the current extreme value.

Optionally, after the switch control circuit controls the first switch to turn off, the second switch remains on, and a current in a power circuit continues to form a loop through the second switch and a parasitic diode of the first switch until the current in the loop reaches the extreme value, at which the switch control circuit controls the second switch to turn off.

Optionally, after receiving the off enable signal, and until the current in the branch where the electronic switch is located reaches the current extreme value, the switch control circuit controls the first switch and the second switch to turn off at the current extreme value.

Optionally, the switch control circuit includes a first switch control circuit and a second switch control circuit.

The first switch control circuit generates a first switch signal based on a voltage at the high-potential terminal and a first reference voltage to control a switching state of the first switch.

The first second control circuit generates a second switch signal based on a voltage at the low potential terminal and a second reference voltage to control a switching state of the second switch. A terminal where the first switch and the second switch are connected is a common connection terminal. The other end of the first switch is connected to the high-potential terminal, and the other end of the second switch is connected to the low-potential terminal. The common connection terminal of the first switch and the second switch transistor is connected to a reference ground terminal. The first reference voltage is set to be less than a voltage at the reference ground terminal, and the second reference voltage is set to be greater than the voltage at the reference ground terminal.

According to a second aspect of the present disclosure, a power supply circuit is provided that includes the aforementioned arc-extinguishing switching device, wherein the switching device is connected between a high-potential terminal and a low-potential terminal of the power supply circuit. The power supply circuit generates an on enable signal/off enable signal according to its operating state, and the switching device operates according to the on enable signal/off enable signal.

The present disclosure discloses an arc-extinguishing switching device and a power supply circuit. By replacing a mechanical switch of an original circuit breaker with a switching device including a mechanical magnetic switch and an electronic switch connected in parallel, during a disconnection process, the magnetic switch is disconnected first, followed by the electronic switch. The electronic switch may be controlled to turn off at a zero current value, thereby avoiding arcing during disconnection. The switching device of embodiments of the present disclosure does not require a special arc-extinguishing gas, and eliminates arcing during the disconnection process. The overall system is simple, highly reliable, has a long service life, and is low in cost.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a circuit diagram of an example switching device according to embodiments of the present disclosure;

FIG. 2 is a circuit diagram of an example implementation of the switching device according to embodiments of the present disclosure; and

FIG. 3 is a circuit diagram of a voltage drop detection circuit according to embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Furthermore, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

Various embodiments of the present disclosure are described in detail below with reference to the accompanying drawings, however, the present disclosure is not limited to these embodiments. The present disclosure covers any substitutions, modifications, and equivalent methods and solutions made within the spirit and scope of the present disclosure.

To facilitate a thorough understanding of the present disclosure, specific details are described in detail in the following embodiments of the present disclosure, but those skilled in the art can fully understand the present disclosure without these details.

The present disclosure is described in more detail below by way of example with reference to the accompanying drawings. It should be noted that the drawings are in a simplified form and use non-precise proportions, and are only used to facilitate and clarify the illustration of the embodiments of the present disclosure.

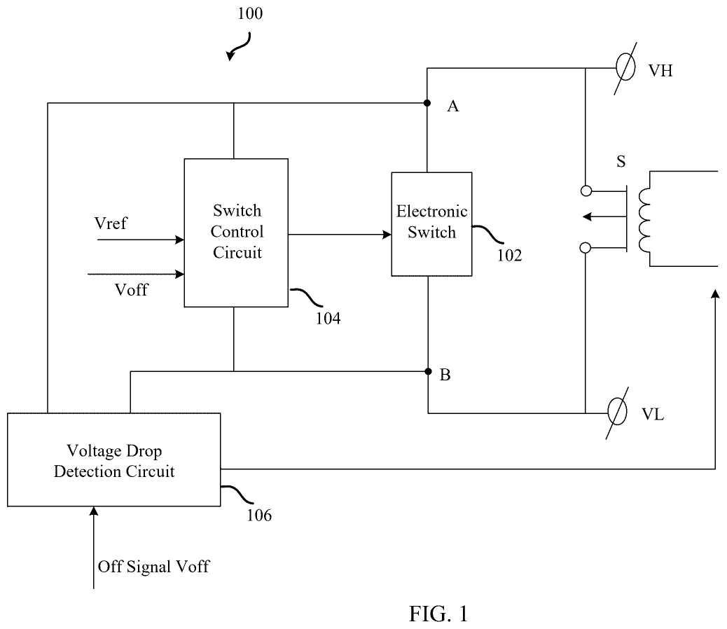

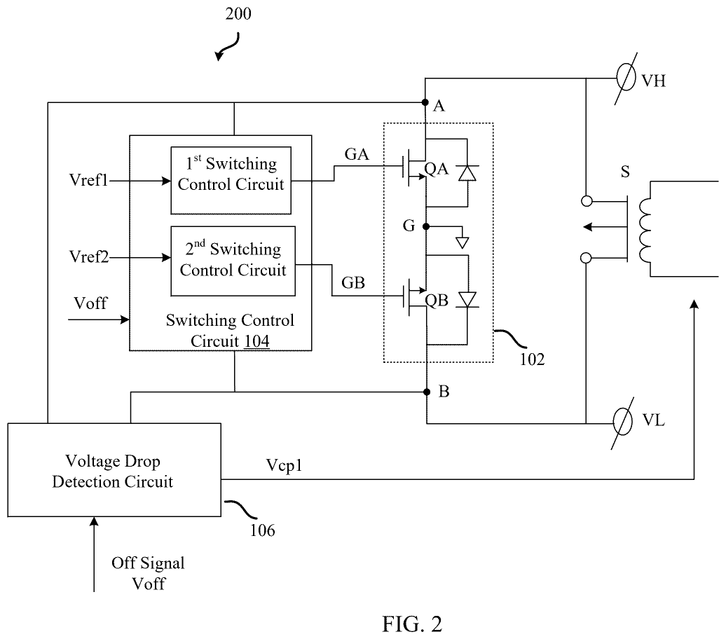

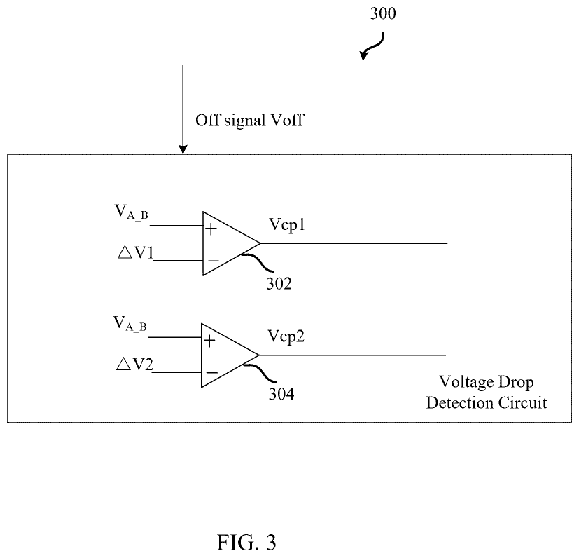

FIG. 1 is a circuit diagram of a switching device 100 according to embodiments of the present disclosure. FIG. 2 is a circuit diagram 200 of an example implementation of the switching device 100 according to embodiments of the present disclosure. FIG. 3 is a circuit diagram of a voltage drop detection circuit 300 according to embodiments of the present disclosure.

In a power grid system such as an AC system (AC power supply system), a switching device such as a circuit breaker or an air switch is used as an operating device to switch on/off the system. The switching device may be connected to two terminals of the AC system. Embodiments of the present disclosure provide the switching device 100 that is configured to switch on/off an AC system or power supply system. As shown in FIG. 1, the switching device 100 may be connected to a high-potential terminal VH and a low-potential terminal VL of the AC system. As shown in FIG. 1 and FIG. 2, the switching device 100 of this example includes a mechanical switch S and an electronic switch 102 connected between the high-potential terminal VH and the low-potential terminal VL. The mechanical switch S and the electronic switch 102 may be connected in parallel. The mechanical switch S may be a magnetic switch or other types of mechanical switches, and in this example, the magnetic switch is used as an example. The on-state voltage drop of the mechanical switch S is generally less than or equal to 200 microohms (mΩ).

The electronic switch 102 may include transistor switch(es), and a switch control circuit 104 is provided to control the state of the transistor switch(es). The terms of “transistor switch” and “switch” are used interchangeably. The electronic switch 102 may be a bidirectional switch combination. As shown in FIG. 2, the electronic switch 102 may include a first switch QA and a second switch QB connected in series. The body diodes of the first switch QA and second switch QB are in opposite directions. The electronic switch 102 may also be other switch combinations, such as a combination of a transistor and a diode. In this embodiment, a field-effect transistor is used as an example of the transistor switches QA and QB, however, other types of transistor switches may also be used.

Further, as shown in FIG. 1 and FIG. 2, the switching device 100 may also include a voltage drop detection circuit (or module) 106. When the switching device 100 receives an off enable signal Voff, the voltage drop detection circuit 106 and the electronic switch 102 start entering an operation state (start operating). In some embodiments, the voltage drop detection circuit 106 and the switch control circuit 104 may respectively receive the off enable signal Voff, controlling the voltage drop detection circuit 106 and the electronic switch 102 to enter the operation state. In some embodiments, the voltage drop detection circuit 106 may receive the off enable signal Voff, which controls the voltage drop detection circuit 106 to enter the operation state, and generates a trigger signal transmitted to an electronic switch circuit 104 to control the electronic switch 102 to enter the operation state.

The voltage drop detection circuit 106 is configured to detect the voltage between the high-potential terminal VH and the low-potential terminal VL. When the detected voltage drops below a preset first voltage threshold ΔV1, a first trigger signal Vcp1 is generated to control the magnetic switch S to open (turn off). The first voltage threshold ΔV1 may be set to any value whose absolute value is less than 10 mV, for example, ΔV1 may be any value less than 5 mV.

After the magnetic switch S is turned off, the switch control circuit 104 detects the current in the branch where the electronic switch 102 is located and controls the electronic switch 102 to turn off when the current reaches an extreme value, which is zero or close to zero. For example, the current herein may be the current flowing through a node A, a node B or the electronic switch 102. In one embodiment, the switch control circuit 104 controls one of the first switch QA and the second switch QB, whichever is to be turned off later, to turn off at the current's extreme value. For example, the switch control circuit 104 may turn off the first switch QA, the second switch QB may remain on, and the current in a power circuit continues to form a loop through the second switch QB and the parasitic diode of the first switch QA until the current in a loop (i.e., the current in the branch where the electronic switch 102 is located, where the loop is formed by the electronic switch and the terminals VH and VL) reaches the extreme value, at which time the switch control circuit 104 controls the second switch QB to turn off. As used herein, the power circuit refers to the loop formed by the electronic switch and the terminals VH and VL. In another embodiment, after the switch control circuit 104 receives an off enable signal, and until the current in the loop where the electronic switch 102 is located reaches the extreme value, the switch control circuit 104 controls the first switch QA and the second switch QB to turn off at the current's extreme value. Here, the switch control circuit 104 may determine whether the current in the branch where the electronic switch 102 is located has reached the extreme value by performing voltage detection.

As shown in FIG. 2 as an example, the switch control circuit 104 may include a first switch control circuit and a second switch control circuit. The first switch control circuit may be configured to generate a first switch signal GA based on the voltage at the high-potential terminal VH and a first reference voltage Vref1 to control the switching state of the first switch QA. The second switch control circuit is configured to generate a second switch signal GB based on the voltage at the low-potential terminal VL and a second reference voltage Vref2 to control the switching state of the second switch QB. The first switch QA and the second switch QB are connected at an node which is a common connection terminal. The other terminal of the first switch QA is connected to the high-potential terminal, and the other terminal of the second switch QB is connected to the low-potential terminal. The common connection terminal of the first switch QA and the second switch QB is connected to a reference ground terminal.

In other words, the first switch QA and the second switch QB are connected in series at a common node which is connected to the reference ground terminal G. The first switch QA is connected between the common node and the node A which is connected to the high-potential terminal VH. The second switch QB is connected between the common node and the node B which is connected to the low-potential terminal VL. The first switch signal GA is connected to the gate (or control terminal) of the first switch QA, controlling to turn on/off QA. The second switch signal GB is connected to the gate (or control terminal) of the second switch QB, controlling to turn on/off QB.

The first reference voltage Vref1 may be set to be less than the voltage at the reference ground terminal G, and the second reference voltage Vref2 may be set to be greater than the voltage at the reference ground terminal G. The first switch control circuit and the second switch control circuit each may be implemented using a circuit formed by an error amplifier and a switch, which is not shown here. By amplifying the error at the input terminal of the circuit, an error amplification signal is generated to control the switching state of the first switch QA and the second switch QB.

FIG. 3 is a circuit diagram 300 of an example for implementing the voltage drop detection circuit 106 according to embodiments of the present disclosure. The example may include a first comparator 302, which is configured to compare a preset voltage difference V_{A_B} between the high-potential terminal and the low-potential terminal with a preset first voltage threshold ΔV1 to generate the first trigger signal Vcp1. The voltage difference V_{A_B} is the voltage between the nodes A and B of FIG. 1 and FIG. 2. Since the voltage signals at the high-potential terminal and the low-potential terminal are alternating signals, the voltage difference V_{A_B} may be positive or negative. In an embodiment, two comparators may be used to compare the positive and negative values. The corresponding first voltage threshold may also include a positive threshold and a negative threshold. In another embodiment, the voltage difference signal V_{A_B} between the high-potential terminal and the low-potential terminal may first be converted into an absolute value, and then compared with the preset first voltage threshold ΔV1. In this case, one comparator and one comparison threshold may be used.

According to the above scheme, after receiving the off signal, and when detecting that the absolute value of the voltage difference between the high-potential terminal and the low-potential terminal reaches the preset first voltage threshold ΔV1, the voltage drop detection module 106 generates the first trigger signal Vcp1 to control the magnetic switch S to open (turn off). Then, the switch control circuit 104 may control the first switch QA and the second switch QB to further turn off. For example, after a first transistor such as QB turns off, the current may continue to flow through the body diode of the first transistor, and the first transistor is safely turned off. Afterwards, since a high current is flowing through a second transistor such as QA, if the second transistor is directly turned off, the large induced energy generated by the current transformer will break down the second transistor. Therefore, by waiting for the current in the power circuit to reach an extreme value, such as zero or close to zero, and then turning off the second transistor, the second transistor can be safely turned off, thus achieving the purpose of safe turning-off of the entire system. During the entire turn-off process, no large current is generated; therefore, no arcing phenomenon occurs in either the mechanical switch or the electronic switch, eliminating the arcing phenomenon in the switching device. The scheme of the present disclosure does not have a complex gas circuit, has high reliability and low switching losses, and improves the service life of the switching device.

In some embodiments, during normal operation of the switching device 100 as a conducting device, the magnetic switch S is turned on (closed), and the electronic switch 102 may be either turned on or off. Since the on-resistance of the electronic switch 102 is much greater than that of the mechanical switch, during the normal operation, the current in the power circuit primarily flows through the branch of the mechanical switch S, resulting in lower risk of damage to the electronic switch 102.

In some embodiments, in order to avoid false detection by the voltage drop detection module 106 due to abnormal interference in the circuit, which may cause the magnetic switch to erroneously turn off (open), when detecting, after the magnetic switch S is turned off by the first trigger signal Vcp1, that the voltage between the high-potential terminal and the low-potential terminal is greater than a preset second voltage threshold ΔV2, the voltage drop detection module 106 may be configured to generate a second trigger signal Vcp2 to control the magnetic switch S to turn on (close). After the magnetic switch is turned on, and if the abnormal interference is resolved, the system enters a normal operating procedure, where when the voltage drop detection module 106 detects again that the voltage between the high-potential terminal and the low-potential terminal is less than the preset first voltage threshold ΔV1, the magnetic switch S is controlled to turn off, and the system operates in a similar manner to what is previously described.

As shown in FIG. 3, the voltage drop detection module 106 may compare the voltage V_{A_B} between the high-potential terminal and the low-potential terminal with the second voltage threshold ΔV2 using a second comparator 304 to generate the second trigger signal Vcp2. In an example, the second voltage threshold ΔV2 may be any value greater than 1V. The second voltage threshold ΔV2 may be set to be much greater than the first voltage threshold ΔV1, which ensures that the system will not switch back and forth due to the voltage threshold setting.

In some embodiments, a power supply circuit is provided, which includes the aforementioned arc-extinguishing switching device (e.g., the switching device 100). The switching device is connected between a high-potential terminal and a low-potential terminal of the power supply circuit. The power supply circuit is configured to generate an on enable signal/off enable signal according to its operating state, and the switching device is configured to operate according to the on enable signal/off enable signal. The on enable signal/off enable signal may be a user trigger signal or a control signal transmitted from a host computer.

As an example, the power supply circuit may generate the on enable signal triggering the mechanical switch S to close, and the power supply circuit starts operation, while the electronic switch 102 remains off. The power supply circuit may generate the off enable signal triggering the mechanical switch S to open, and triggering the switching device 100 to operate as described above, to turn off the electronic switch 102.

In some embodiments, a switching device of a power supply system is provided for switching on/off the power supply system. The switching device is similar to the switching device 100 as described above. The switching device may include a mechanical switch and an electronic switch connected in parallel between a high-potential terminal and a low-potential terminal of the power supply system, a switch control circuit and a voltage drop detection circuit. The switch control circuit is configured to control to turn on/off the electronic switch. The voltage drop detection circuit is configured to detect the voltage across the high-potential terminal and the low-potential terminal of the power supply system, and generate a trigger signal to open or close the mechanical switch based on the detected voltage and a threshold. When the mechanical switch is opened, the switch control circuit is configured to detect a current flowing through the electronic switch, and control to turn off the electronic switch when the current reaches a current threshold, which may be zero (0) or close to zero.

It should be noted that the specific implementations and corresponding drawings provided are merely one way of describing the implementation methods of the present disclosure, and are not intended to limit the specific structure of the implementation schemes of the present disclosure. Various changes or modifications can be made to the implementation schemes without departing from the principle and essence of the present disclosure, but all such changes and modifications fall within the protection scope of the present disclosure.

Although the embodiments are described and illustrated separately above, those ordinarily skilled in the art would recognize that, certain involved common technologies may may be replaced or integrated between the embodiments, and for content not explicitly described in one embodiment, reference may be made to another embodiment that has the content described.

The embodiments described above do not constitute a limitation on the scope of protection of the technical solution. Any modifications, equivalent substitutions, and improvements made within the spirit and principle of the above embodiments should be included within the protection scope of the technical solution.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed:

1. A switching device for extinguishing electric arc, the switching device being connected between a high-potential terminal and a low-potential terminal, and the switching device comprising:
a mechanical switch and an electronic switch connected between the high-potential terminal and the low-potential terminal, the magnetic switch and the electronic switch being arranged in parallel;
a voltage drop detection circuit, wherein the voltage drop detection circuit and the electronic switch are configured to start operation when the switching device receives an off enable signal, the voltage drop detection circuit is further configured to: detect a voltage between the high-potential terminal and the low-potential terminal, and when the detected voltage drops to be less than a preset first voltage threshold, generate a first trigger signal to control the magnetic switch to open; and
a switch control circuit, configured to detect a current in a branch where the electronic switch is located and control the electronic switch to turn off when the current reaches an extreme value, the extreme value being zero or close to zero.

2. The switching device of claim 1, wherein the switch control circuit is further configured to, after the magnetic switch is controlled to open by use of the first trigger signal, control the electronic switch to remain on.

3. The switching device of claim 2, wherein the voltage drop detection circuit is further configured to, after the magnetic switch is controlled to open by the first trigger signal, and when detecting that the voltage between the high-potential terminal and the low-potential terminal is greater than a preset second voltage threshold, generate a second trigger signal to control the magnetic switch to close, wherein the second voltage threshold is any value greater than 1V.

4. The switching device of claim 1, wherein an absolute value of the preset first voltage threshold is any value less than 10 mV.

5. The switching device of claim 1, wherein the electronic switch is a bidirectional switch combination.

6. The switching device of claim 5, wherein the electronic switch comprises a first switch and a second switch connected in series, body diodes of the first switch and the second being in opposite directions; and
wherein the switch control circuit is further configured to control one switch that is turned off later in the first switch and the second switch to turn off at the extreme value of the current.

7. The switching device of claim 6, wherein the switch control circuit is further configured to:
control the first switch to turn off, and keep the second switch on; and
when a current in a power circuit flowing through the second switch and a parasitic diode of the first switch reaches the extreme value, control the second switch to turn off.

8. The switching device of claim 6, wherein the switch control circuit comprises:
a first switch control circuit, configured to generate a first switch signal based on a voltage at the high-potential terminal and a first reference voltage to control a switching state of the first switch; and
a second switch control circuit, configured to generate a second switch signal based on a voltage at the low-potential terminal and a second reference voltage to control a switching state of the second switch;
wherein a terminal where the first switch and the second switch are connected is a common connection terminal, another terminal of the first switch is connected to the high-potential terminal, and another terminal of the second switch is connected to the low-potential terminal; and
wherein, the common connection terminal connecting the first switch and the second switch is connected to a reference ground terminal, the first reference voltage is set to be less than a voltage at the reference ground terminal, and the second reference voltage is set to be greater than the voltage at the reference ground terminal.

9. The switching device of claim 5, wherein the electronic switch comprises a first switch and a second switch connected in series, body diodes of the first switch and the second being in opposite directions; and
the switch control circuit is further configured to:
after receiving the off enable signal, and when the current in the branch where the electronic switch is located reaches the extreme value, control the first switch and the second switch to turn off.

10. The switching device of claim 9, wherein the switch control circuit comprises:
a first switch control circuit, configured to generate a first switch signal based on a voltage at the high-potential terminal and a first reference voltage to control a switching state of the first switch; and
a second switch control circuit, configured to generate a second switch signal based on a voltage at the low-potential terminal and a second reference voltage to control a switching state of the second switch;
wherein a terminal where the first switch and the second switch are connected is a common connection terminal, another terminal of the first switch is connected to the high-potential terminal, and another terminal of the second switch is connected to the low-potential terminal; and
wherein, the common connection terminal connecting the first switch and the second switch is connected to a reference ground terminal, the first reference voltage is set to be less than a voltage at the reference ground terminal, and the second reference voltage is set to be greater than the voltage at the reference ground terminal.

11. A power supply circuit, comprising:
a switching device for extinguishing arc, the switching device being connected between a high-potential terminal and a low-potential terminal of the power supply circuit, and the switching device comprising:
a mechanical switch and an electronic switch connected between the high-potential terminal and the low-potential terminal, the magnetic switch and the electronic switch being connected in parallel;
a voltage drop detection circuit, wherein the voltage drop detection circuit and the electronic switch are configured to start operation when the switching device receives an off enable signal, the voltage drop detection circuit is further configured to: detect a voltage between the high-potential terminal and the low-potential terminal, and when the detected voltage drops to be less than a preset first voltage threshold, generate a first trigger signal to control the magnetic switch to open; and
a switch control circuit, configured to detect a current in a branch where the electronic switch is located, and control the electronic switch to turn off when the current reaches an extreme value, the extreme value being zero or close to zero;
wherein the power supply circuit is configured to generate an on enable signal or the off enable signal according to a working state, and the switching device is configured to operate according to the on enable signal and the off enable signal.

12. The power supply circuit of claim 11, wherein the switch control circuit is further configured to, after the magnetic switch is controlled to open by use of the first trigger signal, control the electronic switch to remain on.

13. The power supply circuit of claim 12, wherein the voltage drop detection circuit is further configured to, after the magnetic switch is controlled to open by the first trigger signal, and when detecting that the voltage between the high-potential terminal and the low-potential terminal is greater than a preset second voltage threshold, generate a second trigger signal to control the magnetic switch to close, wherein the second voltage threshold is any value greater than 1V.

14. The power supply circuit of claim 11, wherein an absolute value of the preset first voltage threshold is any value less than 10 mV.

15. The power supply circuit of claim 11, wherein the electronic switch is a bidirectional switch combination.

16. The power supply circuit of claim 15, wherein the electronic switch comprises a first switch and a second switch connected in series, body diodes of the first switch and the second being in opposite directions; and
wherein the switch control circuit is further configured to control one switch that is turned off later in the first switch and the second switch to turn off at the extreme value of the current.

17. The power supply circuit of claim 16, wherein the switch control circuit is further configured to:
control the first switch to turn off, and keep the second switch on; and
when a current in a power circuit flowing through the second switch and a parasitic diode of the first switch reaches the extreme value, control the second switch to turn off.

18. The power supply circuit of claim 16, wherein the switch control circuit comprises:
a first switch control circuit, configured to generate a first switch signal based on a voltage at the high-potential terminal and a first reference voltage to control a switching state of the first switch; and
a second switch control circuit, configured to generate a second switch signal based on a voltage at the low-potential terminal and a second reference voltage to control a switching state of the second switch;
wherein a terminal where the first switch and the second switch are connected is a common connection terminal, another terminal of the first switch is connected to the high-potential terminal, and another terminal of the second switch is connected to the low-potential terminal; and
wherein, the common connection terminal connecting the first switch and the second switch is connected to a reference ground terminal, the first reference voltage is set to be less than a voltage at the reference ground terminal, and the second reference voltage is set to be greater than the voltage at the reference ground terminal.

19. The power supply circuit of claim 15, wherein the electronic switch comprises a first switch and a second switch connected in series, body diodes of the first switch and the second being in opposite directions; and
the switch control circuit is further configured to:
after receiving the off enable signal, and when the current in the branch where the electronic switch is located reaches the extreme value, control the first switch and the second switch to turn off.

20. The power supply circuit of claim 19, wherein the switch control circuit comprises:
a first switch control circuit, configured to generate a first switch signal based on a voltage at the high-potential terminal and a first reference voltage to control a switching state of the first switch; and
a second switch control circuit, configured to generate a second switch signal based on a voltage at the low-potential terminal and a second reference voltage to control a switching state of the second switch;
wherein a terminal where the first switch and the second switch are connected is a common connection terminal, another terminal of the first switch is connected to the high-potential terminal, and another terminal of the second switch is connected to the low-potential terminal; and
wherein, the common connection terminal connecting the first switch and the second switch is connected to a reference ground terminal, the first reference voltage is set to be less than a voltage at the reference ground terminal, and the second reference voltage is set to be greater than the voltage at the reference ground terminal.
